(19) United States
(12) Patent Application Publication
(10) Pub. No.: US 2005/0095539 A1
(43) Pub. Date: May 5, 2005

(54) Exposure method

(75) Inventor: Kouichirou Tsujita, Ibaraki (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Ibaraki (JP)

(21) Appl. No.: 10/973,424

(22) Filed: Oct. 27, 2004

(30) Foreign Application Priority Data
Oct. 31, 2003 (JP) 2003-371465

(51) Int. Cl. G03F 7/00

(52) U.S. Cl. 430/322; 430/290; 430/950

(57) ABSTRACT

An exposure method includes forming a resist film on a substrate to be processed, forming a top anti-reflection coating on the resist film, and irradiating the resist film with exposure light through the top anti-reflection coating. Forming the top anti-reflection coating includes adjusting refractive index and thickness of the top anti-reflection coating to increase a ratio of s-polarized light to p-polarized light in the exposure light entering the resist film.

### BACKGROUND OF THE INVENTION

1. Field of the Invention

The present invention relates to an exposure method capable of preventing resolution degradation due to a polarization phenomenon.

2. Background Art

In photolithography for forming a pattern on a substrate to be processed, such as a Si substrate, projection exposure methods have been used which form a resist film on the substrate to be processed and expose a mask pattern image onto the substrate to be processed through a projection optical system. Further, to reduce the change in the exposure energy absorbed into a resist due to a change in the thickness of the resist film, there has been devised an exposure method which forms a top anti-reflection coating (TARC) of a transparent and low refractive index material on the resist film and irradiates the resist film with exposure light through this top anti-reflection coating.

This conventional exposure method, however, requires adjustment of the refractive index and film thickness of the top anti-reflection coating to achieve the desired effect. This adjustment will be described below. Assume that exposure light enters a top anti-reflection coating 62 provided on a resist 61 from air 63 at an angle normal to the surface of the top anti-reflection coating 62, as shown in FIG. 6.

When multiple reflection occurs, the reflectance M_{ref} of the surface of the top anti-reflection coating 62 is expressed by equation (1).

$${M}_{ref} = \frac{{r}_{62} + {r}_{61} {ⅇ}^{- ⅈ δ}}{1 + {r}_{61} {r}_{62} {ⅇ}^{- ⅈ δ}} \qquad ( Equation 1 )$$

where: r₆₂ is the reflectance of the exposure light incident on the surface of the top anti-reflection coating 62; r₆₁ is the reflectance of the exposure light at the interface between the top anti-reflection coating 62 and the resist 61; and δ is the change in the phase due to the round trip optical path.

The reflectance M_{ref} is zero when the conditions given by equations (2) and (3) below are both met.
r₆₁=r₆₂ (Equation 2)
e^{-iδ}=−1 (Equation 3)

Equation (4) below is derived from equation (2).

$$\frac{{n}_{63} - {n}_{62}}{{n}_{63} + {n}_{62}} = \frac{{n}_{62} - {n}_{61}}{{n}_{62} + {n}_{61}} \qquad ( Equation 4 )$$

where: n₆₁ is the refractive index of the resist 61; n₆₂ is the refractive index of the top anti-reflection coating 62; and n₆₃ is the refractive index of the air 63. Equation (5) below is derived from equation (4) by assuming that the refractive index (n₆₃) of the air is equal to 1.
n₆₂=\sqrt{n₆₁} (Equation 5)

On the other hand, equation (3) reduces to δ=π, which is substituted into equation (6) below.
δ=4 π d₆₂n₆₂/λ (Equation 6 )
where: d₆₂ is the film thickness of the top anti-reflection coating 62; and λ is the wavelength of the exposure light. This yields equation (7) below.
d₆₂=λ/4n₆₂ (Equation 7)
The refractive index and the film thickness of the top anti-reflection coating 62 are adjusted based on equations (5) and (7) thus obtained.

However, the above conventional exposure method was devised assuming that the exposure light enters the top anti-reflection coating at an angle normal to its surface; the method does not take into account the fact that the exposure light may enter the top anti-reflection coating at an oblique angle. Therefore, the conventional exposure method cannot be used when the NA (numerical aperture) of the projection optical system of the aligner is high, since the diffracted light enters the imaging surface at a large oblique angle.

On the other hand, the NA of the projection optical systems of aligners has recently been increased with increasing integration density of semiconductor devices, etc. Various studies have been conducted to determine the influence of polarization of exposure light at high NAs (see, for example, B. Smith, et al., SPIE, vol. 4691 (2002), p. 11-24). A description will be given below of the influence of polarization of exposure light at high NAs.

Exposure light has polarization characteristics and consists of p-polarized light and s-polarized light. P-polarized light refers to light whose electric field oscillates in a plane parallel to the plane of incidence/reflection, while s-polarized light refers to light whose electric field oscillates in a plane perpendicular to the plane of incidence/reflection. The illumination systems of general aligners emit equal amounts of p-polarized light and s-polarized light, which make up an actual optical image.

FIG. 7A shows how two beams of p-polarized light interfere with each other, while FIG. 7B shows how two beams of s-polarized light interfere with each other. In the case of the p-polarized light, since the electric fields of the two beams are not parallel to each other, the difference between the maximum and minimum lengths of the combined field intensity vector is small, as shown in FIG. 7A. This means that the pattern image has a low contrast. In the case of the s-polarized light, on the other hand, since the electric fields of the two beams are parallel to each other, the maximum length of the combined field intensity vector is twice the length of the reference component field intensity vectors, and the minimum length is zero, as shown in FIG. 7B. Therefore, the s-polarized light provides an interference image higher in contrast than that of the p-polarized light.

A description will be given below of how the incident angle affects p-polarized light interference. When the incident angle is considerably smaller than 45 degrees, the difference between the maximum and minimum intensities is large and hence the contrast is high, as shown in FIG. 8A. When the incident angle is 45 degrees, the maximum intensity is equal to the minimum intensity and hence the contrast is zero, as shown in FIG. 8B. When the incident angle exceeds 45 degrees, a contrast reversal occurs, as shown in FIG. 8C.

FIGS. 9A to 9D show intensities calculated assuming that the pattern size is 100 nmL/S, 80 nmL/S, 70 nmL/S, and 60 nmL/S, respectively. Other conditions are such that the wavelength of the exposure light is 193 nm, the lens NA is 0.85, and the illumination is delivered by a dipole (σ_{center}=0.9 and σ_{radius}=0.1). As can be seen from the calculation results, the p-polarized light image is always lower in contrast than the s-polarized light image. Further, unlike the s-polarized light image, the contrast of the p-polarized light image (considerably) decreases with decreasing pattern size. Especially, in the case of the p-polarized light image, a contrast reversal occurs when the pattern size is reduced to 60 nmL/S, significantly reducing the quality of the image formed by the composite light consisting of the s-polarized light and the p-polarized light. That is, the resolution degradation due to the polarization phenomenon becomes more significant with decreasing pattern size.

As described above, the convention exposure method was devised assuming that the exposure light enters the top anti-reflection coating at an angle normal to its surface. It does not take into account the fact that the exposure light may enter the top anti-reflection coating at an oblique angle, making it impossible to prevent resolution degradation due to the polarization phenomenon.

### SUMMARY OF THE INVENTION

The present invention has been devised to solve the above problem. It is, therefore, an object of the present invention to provide an exposure method capable of preventing resolution degradation due to the polarization phenomenon.

According to one aspect of the present invention, an exposure method includes the step of forming a resist film on a substrate to be processed, the step of forming a top anti-reflection coating on the resist film, and the step of irradiating the resist film with exposure light through the top anti-reflection coating. The step of forming the top anti-reflection coating includes adjusting a refractive index and a film thickness of the top anti-reflection coating so as to increase a ratio of s-polarized light to p-polarized light in the exposure light entering the resist film.

Other and further objects, features and advantages of the invention will appear more fully from the following description.

The present invention enables the prevention of resolution degradation due to the polarization phenomenon.

### BRIEF DESCRIPTION OF THE DRAWINGS

FIG. 1 shows the exposure light enters the top anti-reflection coating at an oblique angle.

FIG. 2 shows a relationship of the refractive index of the top anti-reflection coating and the energy of reflected light.

FIG. 3A shows the proportion y when no top anti-reflection coating is provided on the resist film.

FIG. 3B shows the proportion y when a top anti-reflection coating having the determined appropriate refractive index and appropriate film thickness is provided on the resist film.

FIGS. 4A to 4D each show a relationship between the incident angle and the proportion y of the energy of the s-polarized light in the energy of the exposure light absorbed into the resist film when the top anti-reflection coating has a refractive index larger than the appropriate refractive index.

FIGS. 5A and 5B indicate that the present invention can prevent resolution degradation due to the polarization phenomenon to some extent even when the top anti-reflection coating has a refractive index larger than the above appropriate refractive index.

FIG. 6 shows that the exposure light enters the top anti-reflection coating at an angle normal to its surface.

FIG. 7A shows how two beams of p-polarized light interfere with each other.

FIG. 7B shows how two beams of s-polarized light interfere with each other.

FIGS. 8A-8C show how the incident angle affects p-polarized light interference.

FIGS. 9A to 9D show intensities calculated assuming that the pattern size is 100 nmL/S, 80 nmL/S, 70 nmL/S, and 60 nmL/S, respectively.

### DETAILED DESCRIPTION OF THE PREFERRED EMBODIMENTS

### First Embodiment

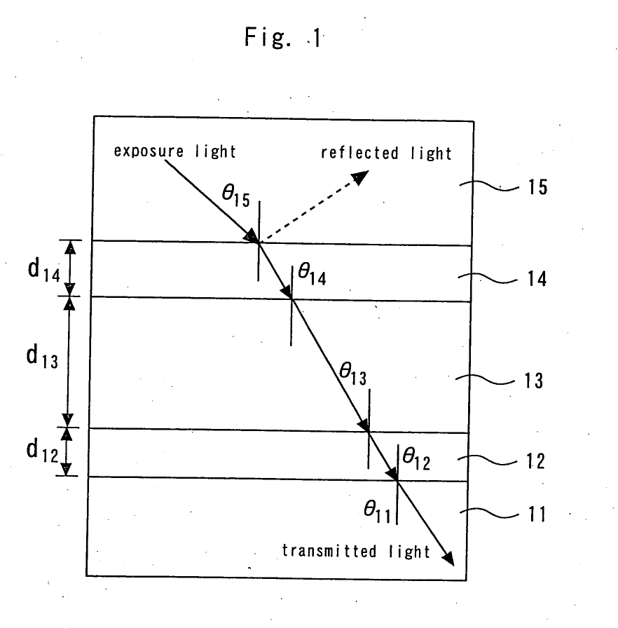

According to a first embodiment of the present invention, as shown in FIG. 1, an exposure method performs the steps of: forming an antireflective film 12 on a Si substrate 11 (a substrate to be processed); forming a resist film 13 on the antireflective film 12; forming a top anti-reflection coating 14 on the resist film 13; and irradiating the resist film 13 with exposure light through the top anti-reflection coating 14. When the top anti-reflection coating 14 is formed, its refractive index and film thickness are adjusted so as to increase the ratio of the s-polarized light to the p-polarized light in the exposure light incident on the resist film 13. Increasing the ratio of the s-polarized light to the p-polarized light can enhance the resolution of the optical image in the resist film 13, since s-polarized light provides higher resolution. A detailed description will be given below of a method for adjusting the refractive index and the film thickness of the top anti-reflection coating. Assume, for example, that exposure light enters the top anti-reflection coating 14 provided on the resist film 13 from air 15 at an oblique angle.

First, an appropriate refractive index and an appropriate film thickness for the top anti-reflection coating 14 is calculated in a conventional manner. This process begins by finding the conditions at which the reflectance M_{ref} given by equation (1) is equal to 0, as described above. Naturally, under these conditions, sufficient amounts of p-polarized light and s-polarized light go into the resist since the reflection of the exposure light from the surface of the top anti-reflection coating is suppressed. Then, equations (2) and (3) are obtained in the same manner as described above. Then, unlike the above example, equations (8) and (9) below for p-polarized light and s-polarized light, respectively, are derived from equation (2) since the exposure light enters the top anti-reflection coating at the oblique angle.

$$\begin{matrix}\frac{{n}_{14} cos {θ}_{15} - {n}_{15} cos {θ}_{14}}{{n}_{14} cos {θ}_{15} + {n}_{15} cos {θ}_{14}} = \frac{{n}_{13} cos {θ}_{14} - {n}_{14} cos {θ}_{13}}{{n}_{13} cos {θ}_{14} + {n}_{14} cos {θ}_{13}} & ( Equation 8 ) \\ \frac{{n}_{15} cos {θ}_{15} - {n}_{14} cos {θ}_{14}}{{n}_{15} cos {θ}_{15} + {n}_{14} cos {θ}_{14}} = \frac{{n}_{14} cos {θ}_{14} - {n}_{13} cos {θ}_{13}}{{n}_{14} cos {θ}_{14} + {n}_{13} cos {θ}_{13}} & ( Equation 9 )\end{matrix}$$

where: n₁₃ is the refractive index of the resist film 13; n₁₄ is the refractive index of the top anti-reflection coating 14; n₁₅ is the refractive index of the air 15; r₁₄ is the reflectance of the exposure light incident on the surface of the top anti-reflection coating 14; r₁₃ is the reflectance of the exposure light at the interface between the top anti-reflection coating 14 and the resist film 13; θ₁₅ is the incident angle at which the exposure light enters the top anti-reflection coating 14 from the air 15 (with respect to a normal line to the top anti-reflection coating 14); θ₁₄ is the incident angle of the exposure light within the top anti-reflection coating 14; and θ₁₃ is the incident angle of the exposure light within the resist film 13.

Equations (10) and (11) below are derived from equation (8) and (9) assuming that the refractive index (n₁₅) of the air is equal to 1.

$$\begin{matrix}{n}_{14} = \sqrt{{n}_{13}} \frac{cos {θ}_{14}}{\sqrt{cos {θ}_{15} cos {θ}_{13}}} & ( Equation 10 ) \\ {n}_{14} = \sqrt{{n}_{13}} \frac{\sqrt{cos {θ}_{15} cos {θ}_{13}}}{cos {θ}_{14}} & ( Equation 11 )\end{matrix}$$

It should be noted that even though the left sides of equations (10) and (11) are the refractive index n₁₄, the right sides of the equations include cos θ₁₄, which is dependent on the refractive index n₁₄. Therefore, these equations cannot be simply used to determine an appropriate refractive index and an appropriate film thickness for the top anti-reflection coating 14. To overcome this problem, the present embodiment uses the following method to determine an appropriate refractive index and an appropriate film thickness for the top anti-reflection coating 14 and an appropriate film thickness for the resist film.

First, a description will be given of equations (12) to (54) employed by the present embodiment. When multiple reflection occurs, the reflectance M_{ref} Of the surface of the top anti-reflection coating 14 is expressed by the following equation.

$${M}_{ref} ( t , b , d ) = \frac{t + bd}{1 + tbd} \qquad ( Equation 12 )$$

Further, the transmittance Mₜᵣₐₙₛ of the exposure light transmitted to the Si substrate 11 is expressed by the following equation.

$${M}_{trans} ( t , b , x , y , d ) = \frac{tb \sqrt{d}}{1 + xyd} \qquad ( Equation 13 )$$

The incident angle θ₁₅ at which the exposure light enters the top anti-reflection coating 14 is expressed by the following equation, using the NA of the aligner.
θ₁₅=arc−sin NA (Equation 14)

Further, equations (15) to (18) below represent the following parameters: the incident angle θ₁₄ of the exposure light within the top anti-reflection coating 14; the incident angle θ₁₃ of the exposure light within the resist film 13; the incident angle θ₁₂ of the exposure light within the antireflective film 12; and the incident angle θ₁₁ of the exposure light within the Si substrate 11.

$$\begin{matrix}{θ}_{14} = arcsin ( \frac{Re [ {n}_{15} ] sin {θ}_{15}}{Re [ {n}_{14} ]} ) & ( Equation 15 ) \\ {θ}_{13} = arcsin ( \frac{Re [ {n}_{15} ] sin {θ}_{15}}{Re [ {n}_{13} ]} ) & ( Equation 16 ) \\ {θ}_{12} = arcsin ( \frac{Re [ {n}_{15} ] sin {θ}_{15}}{Re [ {n}_{12} ]} ) & ( Equation 17 ) \\ {θ}_{11} = arcsin ( \frac{Re [ {n}_{15} ] sin {θ}_{15}}{Re [ {n}_{11} ]} ) & ( Equation 18 )\end{matrix}$$

where: Re[n] represents the real part of n; n₁₂ is the refractive index of the antireflective film 12; and n₁₁ is the refractive index of the Si substrate 11.

Further, equations (19) to (26) below represent the following parameters: the reflectances rₚ₁₄ and rₛ₁₄ of the p-polarized light and s-polarized light, respectively, in the exposure light incident on the surface of the top anti-reflection coating 14; the reflectances rₚ₁₃ and rₛ₁₃ of the p-polarized light and s-polarized light, respectively, in the exposure light at the interface between the top anti-reflection coating 14 and the resist film 13; the reflectances rₚ₁₂ and rₛ₁₂ of the p-polarized light and s-polarized light, respectively, in the exposure light at the interface between the resist film 13 and the antireflective film 12; and the reflectances rₚ₁₁ and rₛ₁₁ of the p-polarized light and s-polarized light, respectively, in the exposure at the interface between the antireflective film 12 and the Si substrate 11.

$$\begin{matrix}{r}_{p14} = \frac{{n}_{14} cos {θ}_{15} - {n}_{15} cos {θ}_{14}}{{n}_{14} cos {θ}_{15} + {n}_{15} cos {θ}_{14}} & ( Equation 19 ) \\ {r}_{s14} = \frac{{n}_{15} cos {θ}_{15} - {n}_{14} cos {θ}_{14}}{{n}_{15} cos {θ}_{15} + {n}_{14} cos {θ}_{14}} & ( Equation 20 ) \\ {r}_{p13} = \frac{{n}_{13} cos {θ}_{14} - {n}_{14} cos {θ}_{13}}{{n}_{13} cos {θ}_{14} + {n}_{14} cos {θ}_{13}} & ( Equation 21 ) \\ {r}_{s13} = \frac{{n}_{14} cos {θ}_{14} - {n}_{13} cos {θ}_{13}}{{n}_{14} cos {θ}_{14} + {n}_{13} cos {θ}_{13}} & ( Equation 22 ) \\ {r}_{p12} = \frac{{n}_{12} cos {θ}_{13} - {n}_{13} cos {θ}_{12}}{{n}_{12} cos {θ}_{13} + {n}_{13} cos {θ}_{12}} & ( Equation 23 ) \\ {r}_{s12} = \frac{{n}_{13} cos {θ}_{13} - {n}_{12} cos {θ}_{12}}{{n}_{13} cos {θ}_{13} + {n}_{12} cos {θ}_{12}} & ( Equation 24 ) \\ {r}_{p11} = \frac{{n}_{11} cos {θ}_{12} - {n}_{12} cos {θ}_{11}}{{n}_{11} cos {θ}_{12} + {n}_{12} cos {θ}_{11}} & ( Equation 25 ) \\ {r}_{s11} = \frac{{n}_{12} cos {θ}_{12} - {n}_{11} cos {θ}_{11}}{{n}_{12} cos {θ}_{12} + {n}_{11} cos {θ}_{11}} & ( Equation 26 )\end{matrix}$$

Further, equations (27) to (34) below represent the following parameters: the transmittances tₚ₁₄ and tₛ₁₄ of the p-polarized light and s-polarized light, respectively, in the exposure light at the interface between the air 15 and the top anti-reflection coating 14; the transmittances tp₁₃ and ts₁₃ of the p-polarized light and s-polarized light, respectively, in the exposure light at the interface between the top anti-reflection coating 14 and the resist film 13; the transmittances tₚ₁₂ and tₛ₁₂ of the p-polarized light and s-polarized light, respectively, in the exposure light at the interface between the resist film 13 and the antireflective film 12; and the transmittances tp₁₁ and ts₁₁ of the p-polarized light and s-polarized light, respectively, in the exposure light at the interface between the antireflective film 12 and the Si substrate 11.

$$\begin{matrix}{t}_{p14} = \frac{2 {n}_{15} cos {θ}_{15}}{{n}_{14} cos {θ}_{15} + {n}_{15} cos {θ}_{14}} & ( Equation 27 ) \\ {t}_{s14} = \frac{2 {n}_{15} cos {θ}_{15}}{{n}_{15} cos {θ}_{15} + {n}_{14} cos {θ}_{14}} & ( Equation 28 ) \\ {t}_{p13} = \frac{2 {n}_{14} cos {θ}_{14}}{{n}_{13} cos {θ}_{14} + {n}_{14} cos {θ}_{13}} & ( Equation 29 ) \\ {t}_{s13} = \frac{2 {n}_{14} cos {θ}_{14}}{{n}_{14} cos {θ}_{14} + {n}_{13} cos {θ}_{13}} & ( Equation 30 ) \\ {t}_{p12} = \frac{2 {n}_{13} cos {θ}_{13}}{{n}_{12} cos {θ}_{13} + {n}_{13} cos {θ}_{12}} & ( Equation 31 ) \\ {t}_{s12} = \frac{2 {n}_{13} cos {θ}_{13}}{{n}_{13} cos {θ}_{13} + {n}_{12} cos {θ}_{12}} & ( Equation 32 ) \\ {t}_{p11} = \frac{2 {n}_{12} cos {θ}_{12}}{{n}_{11} cos {θ}_{12} + {n}_{12} cos {θ}_{11}} & ( Equation 33 ) \\ {t}_{s11} = \frac{2 {n}_{12} cos {θ}_{12}}{{n}_{12} cos {θ}_{12} + {n}_{11} cos {θ}_{11}} & ( Equation 34 )\end{matrix}$$

Further, equations (35) to (37) below represent the following parameters: the phase change δ₁₄ due to the round trip optical path within the top anti-reflection coating 14; the phase change δ₁₃ due to the round trip optical path within the resist film 13; and the phase change δ₁₂ due to the round trip optical path within the antireflective film 12.

$$\begin{matrix}{δ}_{14} = exp ( - ⅈ [ 4 π {d}_{14} \frac{{n}_{14} cos {θ}_{14}}{λ} ] ) & ( Equation 35 ) \\ {δ}_{13} = exp ( - ⅈ [ 4 π {d}_{13} \frac{{n}_{13} cos {θ}_{13}}{λ} ] ) & ( Equation 36 ) \\ {δ}_{12} = exp ( - ⅈ [ 4 π {d}_{12} \frac{{n}_{12} cos {θ}_{12}}{λ} ] ) & ( Equation 37 )\end{matrix}$$

Then, equations (38) to (43) below represent the following parameters: the amplitudes ξₚ₁₄ and ξₛ₁₄ of the p-polarized light and s-polarized light, respectively, in the multiple-reflected light reflected from the surface of the top anti-reflection coating 14; the amplitudes ξₚ₁₃ and ξₛ₁₃ of the p-polarized light and s-polarized light, respectively, in the reflected light multiple-reflected at the interface between the top anti-reflection coating 14 and the resist film 13; and the amplitudes ξₚ₁₂ and ξₛ₁₂ of the p-polarized light and s-polarized light, respectively, in the reflected light multiple-reflected at the interface between the resist film 13 and the antireflective film 12.
ξₚ₁₄=M_{ref}(rₚ₁₄, rₚ₁₃, δ₁₄) (Equation 38)
ξₛ₁₄=M_{ref}(rₛ₁₄, rₛ₁₃, δ₁₄) (Equation 39)
ξₚ₁₃=M_{ref}(rₚ₁₃, ξₚ₁₂, δ₁₃) (Equation 40)
ξₛ₁₃=M_{ref}(rₛ₁₃, ξₛ₁₂, δ₁₃) (Equation 41)
ξₚ₁₂=M_{ref}(rₚ₁₂, rₚ₁₁, δ₁₂) (Equation 42)
ξₛ₁₂=M_{ref}(rₛ₁₂, rₛ₁₁, δ₁₂) (Equation 43)

Then, equations (44) to (49) below represent the following parameters: the amplitudes ηₚ₁₄ and ηₛ₁₄ of the p-polarized light and s-polarized light, respectively, in the transmitted light multiple-reflected at the interface between the air 15 and the top anti-reflection coating 14; the amplitudes ηₚ₁₃ and ηₛ₁₃ of the p-polarized light and s-polarized light, respectively, in the transmitted light multiple-reflected at the interface between the top anti-reflection coating 14 and the resist film 13; and the amplitudes ηₚ₁₂ and ηₛ₁₂ of the p-polarized light and s-polarized light, respectively, in the transmitted light multiple-reflected at the interface between the resist film 13 and the antireflective film 12.
ηₚ₁₄=Mₜᵣₐₙₛ(tₚ₁₃, tₚ₁₃, rₚ₁₄, ξₚ₁₃, δ₁₄) (Equation 44)
ηₛ₁₄=Mₜᵣₐₙₛ(tₛ₁₃, tₛ₁₃, rₛ₁₄, ξₛ₁₃, δ₁₄) (Equation 45)
ηₚ₁₃=Mₜᵣₐₙₛ(ηₚ₁₄, tₚ₁₂, rₚ₁₃, ξₚ₁₂, δ₁₃) (Equation 46)
ηₛ₁₃=Mₜᵣₐₙₛ(ηₛ₁₄, tₛ₁₂, rₛ₁₃, ξₛ₁₂, δ₁₃) (Equation 47)
ηₚ₁₂=Mₜᵣₐₙₛ(ηₚ₁₃, tₚ₁₁, rₚ₁₂, rₚ₁₁, δ₁₂) (Equation 48)
ηₛ₁₂=Mₜᵣₐₙₛ(ηₛ₁₃, tₛ₁₁, rₛ₁₂, rₛ₁₁, δ₁₂) (Equation 49)

Then, equations (50) and (51) below represent the energy Rₚ and Rₛ of the p-polarized light and s-polarized light, respectively, in the multiple-reflected light reflected from the surface of the top anti-reflection coating 14.
Rₚ=|ξₚ₁₄|² (Equation 50)
Rₛ=|ξₛ₁₄|² (Equation 51)

Further, equations (52) and (53) below represent the energy Tₚ and Tₛ of the p-polarized light and s-polarized light, respectively, in the multiple-reflected transmitted light transmitted to the Si substrate 11.

$$\begin{matrix}{T}_{p} = {\vert {η}_{p12} \vert}^{2} ( \frac{Re [ {n}_{11} ] cos {θ}_{11}}{Re [ {n}_{15} ] cos {θ}_{15}} ) & ( Equation 52 ) \\ {T}_{s} = {\vert {η}_{s12} \vert}^{2} ( \frac{Re [ {n}_{11} ] cos {θ}_{11}}{Re [ {n}_{15} ] cos {θ}_{15}} ) & ( Equation 53 )\end{matrix}$$

Then, the proportion y of the energy of the s-polarized light in the energy absorbed into the resist 13 is expressed by the following equation.

$$y = \frac{1 - {R}_{s} - {T}_{s}}{( 1 - {R}_{p} - {T}_{p} ) + ( 1 - {R}_{s} - {T}_{s} )} \qquad ( Equation 54 )$$

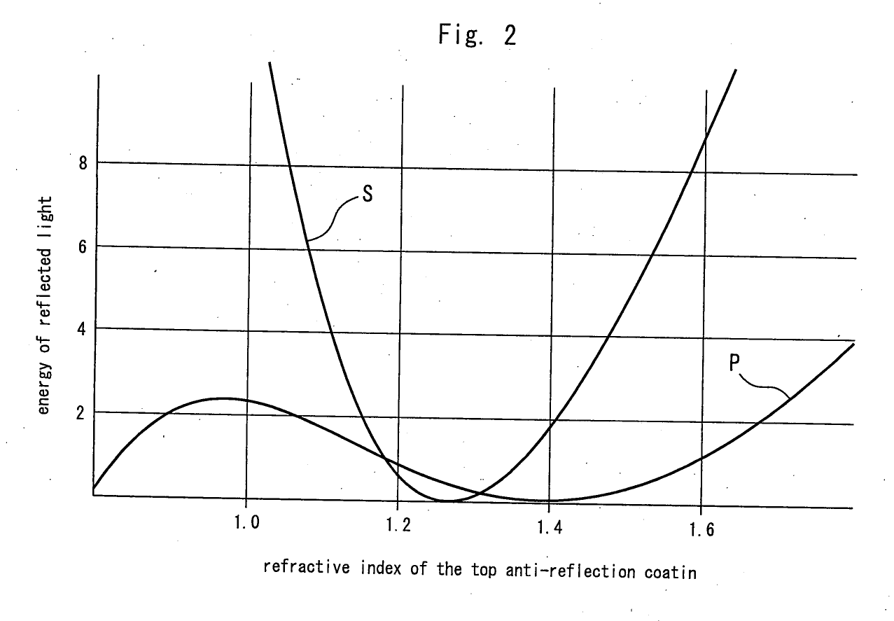

The above equations are used to calculate relationships between the refractive index n₁₄ of the top anti-reflection coating 14 and the energy Tₚ and Tₛ of the p-polarized light and s-polarized light, respectively, in the reflected exposure light reflected from the surface of the top anti-reflection coating 14. It should be noted that when the exposure light enters the top anti-reflection coating 14 at an oblique angle and is transmitted through the top anti-reflection coating 14 at the incident angle θ₁₄, the length of the optical path for the transmitted light within the top anti-reflection coating 14 is d₁₄/cosθ₁₄. Therefore, from equation (7), the film thickness d₁₄ of the top anti-reflection coating 14 is set such that d₁₄=λ/(4*n₁₄*cosθ₁₄). FIG. 2 shows the calculation results. It should be noted that the wavelength λ of the exposure light is set to 193 nm and the NA is set to 0.68.

An appropriate refractive index of the top anti-reflection coating 14 is determined from the calculation results such that the ratio of the energy of the s-polarized light to the energy of the p-polarized light in the reflected light is small. However, the calculation results shown in FIG. 2 indicate that the energy of the s-polarized light and the p-polarized light in the reflected light is minimized at substantially equal refractive indices of the top anti-reflection coating 14. Therefore, let the appropriate refractive index of the top anti-reflection coating 14 be the refractive index at which the energy Rₛ of the s-polarized light is minimized. Accordingly, an appropriate refractive index value of 1.27 is obtained from the graph of FIG. 2. Then, based on this appropriate refractive index value and the equation d₁₄=λ/(4*n₁₄*cosθ₁₄), the appropriate film thickness for the top anti-reflection coating 14 is calculated to be 45 nm. When the top anti-reflection coating 14 is formed, the refractive index and the film thickness of the top anti-reflection coating 14 may be set to these values so as to prevent resolution degradation due to the polarization phenomenon.

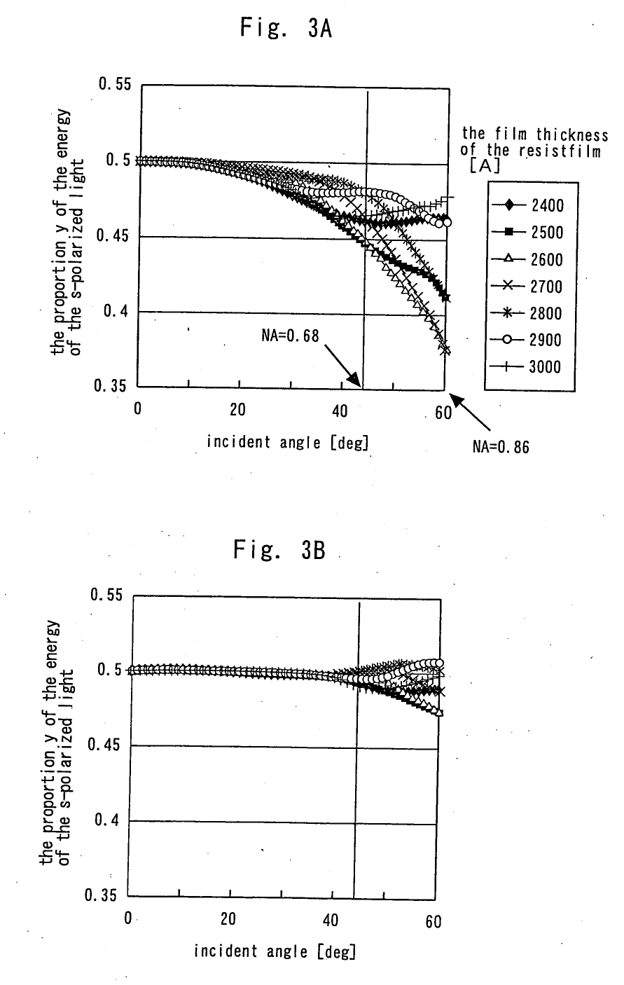

Then, based on the determined appropriate refractive index and appropriate film thickness for the top anti-reflection coating, the proportion y of the energy of the s-polarized light in the energy of the exposure light absorbed into the resist film is calculated for each incident angle of the exposure light incident on the top anti-reflection coating 14 with the thickness of the resist film set to specific values. FIGS. 3A and 3B show the calculation results. It should be noted that other parameters are set such that λ=1930, n₁₁=0.88−2.78i, n₁₂=1.71−0.41i, n₁₃=1.7−0.02i, n₁₄=1.45−0.084i, n₁₅=1, d₁₂=345, d₁₃=2400, and d₁₅=455. Specifically, FIG. 3A shows the proportion y when no top anti-reflection coating is provided on the resist film, while FIG. 3B shows the proportion y when a top anti-reflection coating having the determined appropriate refractive index and appropriate film thickness is provided on the resist film. In each figure, the horizontal axis represents the incident angle of the exposure light, and the vertical axis represents the proportion y of the energy of the s-polarized light in the energy of the exposure light absorbed into the resist film. The film thickness of the resist film is set to 7 different values (2400 Å to 3000 Å, as shown in FIGS. 3A and 3B).

When no top anti-reflection coating is provided, the proportion of the s-polarized light, which provides higher resolution, decreases with increasing incident angle, even though their proportions are substantially equal at small incident angles, as shown in FIG. 3A. Specifically, when the resist film thickness is 260 nm, the proportion of the energy of the s-polarized light is 0.45 (45%) at an incident angle of 43 degrees, which corresponds to an NA of 0.68. The proportion of the energy of the s-polarized-light reduces to 0.37 (37%) if the incident angle is increased to 60 degrees, which corresponds to an NA of 0.86. When the top anti-reflection coating having the adjusted refractive index and film thickness is provided, however, the reduction of the proportion of the energy of the s-polarized light can be prevented even at large incident angles, as shown in FIG. 3B.

Based on these calculation results and the NA of the aligner, an appropriate film thickness for the resist film may be determined so as to increase the proportion of the energy of the s-polarized light. Then, when forming the resist film, the resist film may be set to the determined film thickness, ensuring that the resolution degradation due to the polarization phenomenon can be prevented.

Thus, an optimum refractive index of the top anti-reflection coating 14 is preferably determined based on the calculation results shown in FIG. 2 such that the ratio of the energy of the s-polarized light to the energy of the p-polarized light in the reflected light is minimized. Then, an optimum film thickness for the top anti-reflection coating is preferably determined from the optimum refractive index using the equation: d₁₄=λ/(4*n₁₄*cosθ₁₄). Further, an optimum film thickness for the resist film is preferably determined based on the calculation results shown in FIGS. 3A and 3B and the numerical aperture (NA) of the aligner so as to maximize the proportion of the energy of the s-polarized light in the energy of the exposure light absorbed into the resist film. It should be noted that these parameters may not need to be set to the optimum values, as shown in FIG. 2 and FIGS. 3A and 3B. Each parameter may be set to a value within a predetermined appropriate range. Specifically, the refractive index and the film thickness of the top anti-reflection coating may be set such that the ratio of the s-polarized light to the p-polarized light in the exposure light entering the resist film is more than 10% higher than when no top anti-reflection coating is formed. The effect of such an arrangement can be experimentally observed.

Further, in the above example, the wavelength of the exposure light is set to 193 nm and the NA is set to 0.68. However, the exposure method of the first embodiment is not limited to any particular wavelength or NA value. The method is useful at every exposure light wavelength and every NA value. However, the exposure method of the present invention is especially effective when the wavelength of the exposure light is 193 nm or less or when an aligner having an NA of 0.68 or more is used to irradiate the resist film with the exposure light. It should be noted that the appropriate refractive index range and the appropriate film thickness range for the top anti-reflection coating and the appropriate film thickness range for the resist film vary depending on the value of the NA.

### Second Embodiment

According to the first embodiment, the appropriate refractive index of the top anti-reflection coating is determined to be 1.27. This value is considerably small since the refractive index of conventional top anti-reflection coatings is 1.45. More precisely, conventional top anti-reflection coatings have a complex refractive index of (1.45−0.084i) since slight absorption occurs. Therefore, the exposure method of a second embodiment determines an appropriate film thickness for the top anti-reflection coating and that for the resist film when the top anti-reflection coating is made of a material having a refractive index larger than the above appropriate refractive index (1.27).

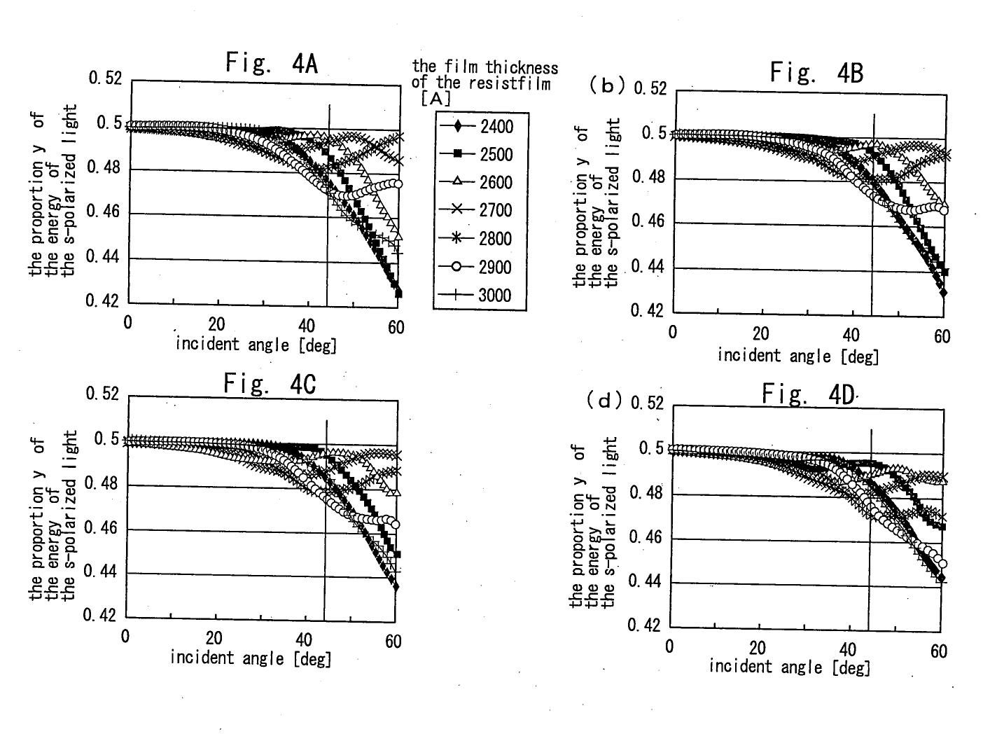

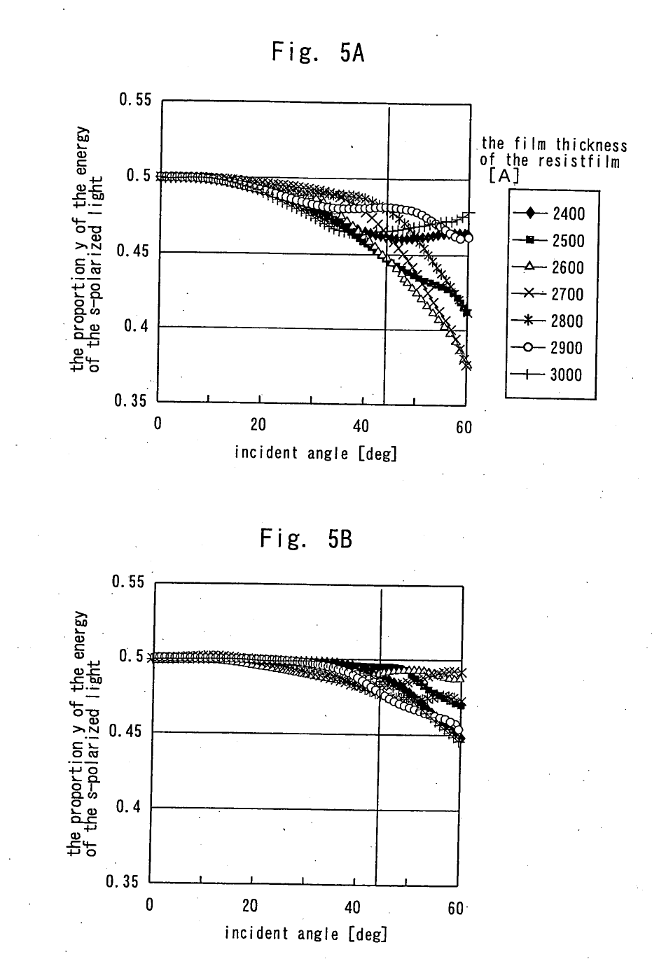

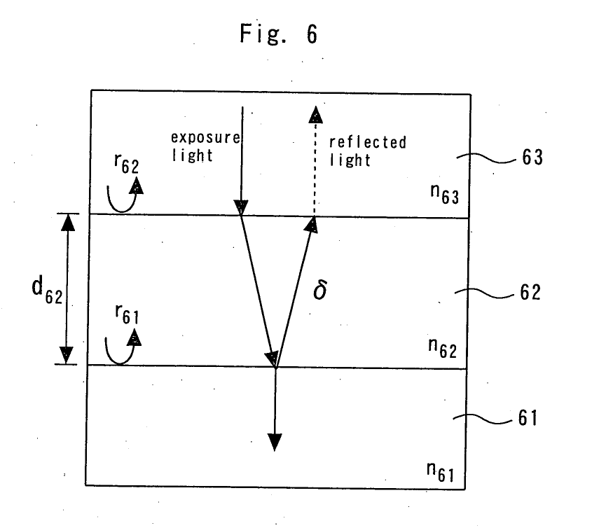

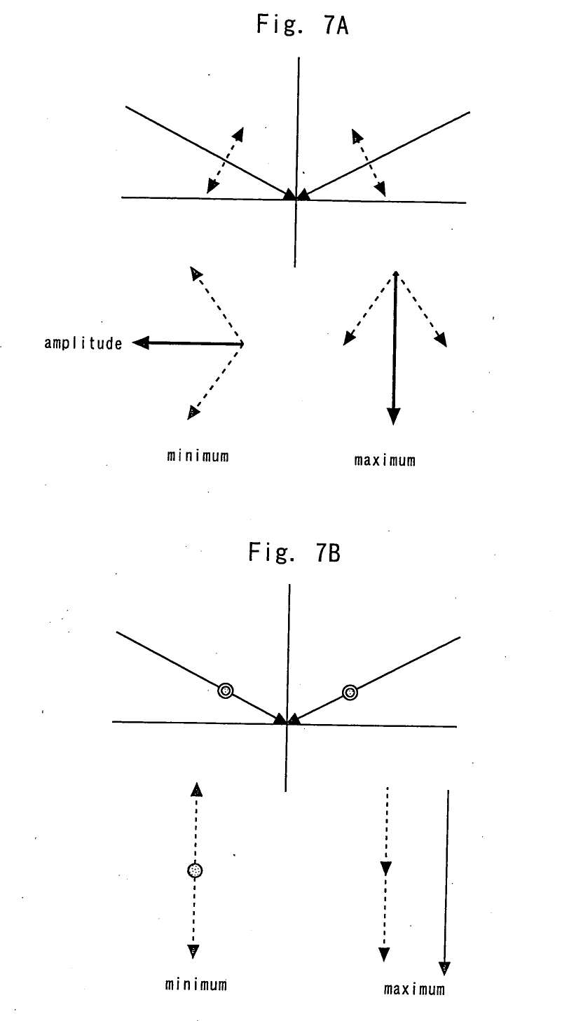

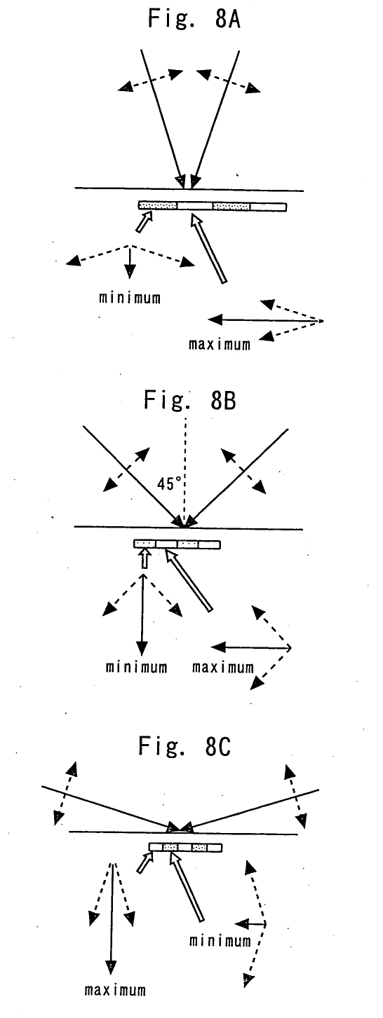

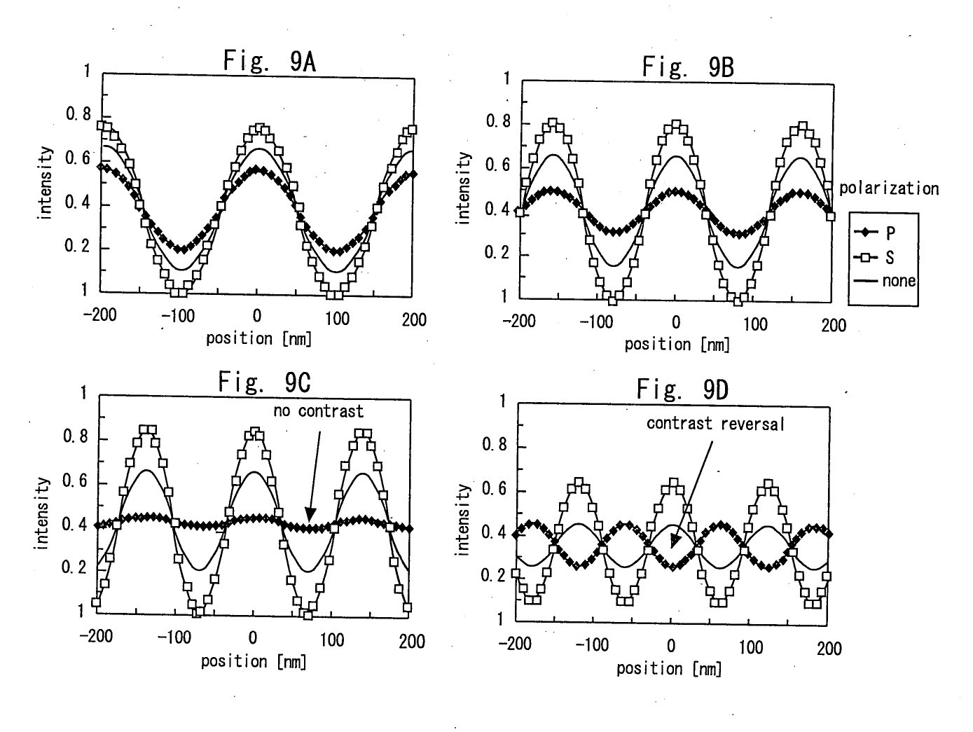

FIGS. 4A to 4D each show a relationship between, the incident angle and the proportion y of the energy of the s-polarized light in the energy of the exposure light absorbed into the resist film when the top anti-reflection coating has a refractive index larger than the appropriate refractive index. The proportion y was calculated in the same manner as described above. Specifically, FIGS. 4A to 4D show the calculation results obtained when the film thickness of the top anti-reflection coating is set to 333 Å, 377 Å, 400 Å, and 455 Å, respectively. As can be seen from the calculation results, an appropriate film thickness for the top anti-reflection coating may not be given by the equation: d₁₄=λ/(4*n₁₄*cosθ₁₄). A film thickness larger than that calculated by the equation may be more effective. This is because the top anti-reflection coating does not have an appropriate refractive index. FIG. 5A shows a relationship between the incident angle and the proportion y when the film thickness of the top anti-reflection coating is set to 455 Å. FIG. 5B, on the other hand, shows a relationship between the incident angle and the proportion y when no top anti-reflection coating is provided. FIGS. 5A and 5B indicate that the present invention can prevent resolution degradation due to the polarization phenomenon to some extent even when the top anti-reflection coating has a refractive index larger than the above appropriate refractive index.

Based on the above calculation results and the NA of the aligner, an appropriate film thickness for the top anti-reflection coating and an appropriate film thickness for the resist film may be determined so as to increase the proportion of the energy of the s-polarized light. Then, when the top anti-reflection coating and the resist film are formed, they may be set to the respective determined appropriate film thicknesses, allowing the resolution degradation due to the polarization phenomenon to be prevented.

It should be noted that if the device has large surface irregularities, the above film thickness adjustment has only small effect in preventing resolution degradation since the film thickness of the resist may vary at each location. However, currently produced devices have substantially no significant surface irregularities since a standardized CMP process is used. Therefore, the above film thickness adjustment is important.

A description will be given below of the results of an exposure experiment conducted to determine the effects of the exposure method of the present embodiment. The exposure conditions were such that the wavelength of the exposure light was 193 nm (ArF), the NA of the lens was 0.68, and σ for the illumination was 0.3. Since an alternating PSM (phase shift mask) of 90 nmL/S was used, two-beam interference occurred. Further, since the mask has a fine pattern, the beam went through the lens pupil near its outermost circumference, forming an incident angle close to the maximum incident angle which can be attained by this lens. Further, a was set small, reducing the incident angle distribution. These exposure conditions substantially coincide with those for the above calculation. Further, the thicknesses of the resist film and the antireflective film provided between the resist film and the substrate were set to 250 nm and 78 nm, respectively.

Table 1 below lists the results of evaluating lithographic margins obtained under the above exposure conditions when a top anti-reflection coating having a film thickness of 33 nm was provided and when no top anti-reflection coating was provided.

TABLE 1

| | | |
|---|---|---|
| Top anti-reflection | 33 nm | None |
| coating | | |
| Eo/Ec | 1.42 | 1.23 |
| Exposure latitude | 8.7% | 6.2% |
| DOF | 0.6 μm | 0.7 μm |

In the table, Eo denotes the exposure time required to form a pattern of 90 nmL/S, and Ec denotes the exposure time required to separate patterns by removing the bridges therebetween. The larger the value of Eo/Ec, the greater the margin for removal of the bridges. Exposure latitude refers to an exposure margin defined as the change (%) in light exposure required to change the size by 10%. That is, the larger the exposure latitude, the smaller the influence of the light exposure on the size and hence the better. DOF refers to a focus margin defined as the focal range over which the size changes by 10%. The larger the DOF, the better. It should be noted that the top anti-reflection coating was set to a film thickness of 33 nm. The reason for this is that even though this value is a little different from the appropriate film thickness, the top anti-reflection coating is effective to some extent, as can be seen from the calculation results shown in FIG. 4A. Further, the resist film was set to a film thickness of 250 nm, since such an arrangement increases the proportion of the energy of the s-polarized light in the energy of the exposure light absorbed into the resist film when the top anti-reflection coating is provided, as can be seen from the calculation results shown in FIGS. 5A and 5B.

The experimental results listed in Table 1 indicate that there were improvements in the parameter Eo/Ec and the exposure latitude. It should be noted that these parameters are related to the contrast of the optical image. Therefore, the experimental results demonstrate the effects of the present invention. It should be further noted that the present invention cannot improve the DOF, as shown by the experimental results. The experimental results show that the exposure method of the present invention can prevent resolution degradation due to the polarization phenomenon.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2003-371465, filed on Oct. 31, 2003 including specification, claims, drawings and summary, on which the Convention priority of the present application is based, are incorporated herein by reference in its entirety.

1. An exposure method comprising:
forming a resist film on a substrate to be processed;
forming a top anti-reflection coating on the resist film; and
irradiating the resist film with exposure light through the top anti-reflection coating, wherein forming the top anti-reflection coating includes adjusting refractive index and thickness of the top anti-reflection coating to increase ratio of s-polarized light to p-polarized light in the exposure light entering the resist film.

2. The exposure method as claimed in claim 1, wherein forming the top anti-reflection coating includes adjusting the refractive index and the thickness of the top anti-reflection coating such that the ratio of the s-polarized light to the p-polarized light in the exposure light entering the resist film is more than 10% higher than when the top anti-reflection coating is not present.

3. The exposure method as claimed in claim 1, wherein forming the top anti-reflection coating includes adjusting the refractive index and the thickness of the top anti-reflection coating to maximize the ratio of the s-polarized light to the p-polarized light in the exposure light entering the resist film.

4. The exposure method as claimed in claim 1, wherein:
the top anti-reflection coating is a material having a first refractive index; and
forming the top anti-reflection coating includes adjusting the thickness of the top anti-reflection coating to increase the ratio of the s-polarized light to the p-polarized light in the exposure light entering the resist film.

5. The exposure method as claimed in claim 1, wherein the exposure light enters the top anti-reflection coating at an oblique angle.

6. The exposure method as claimed in claim 5, further comprising:
calculating relationships between the refractive index of the top anti-reflection coating and energy of the s-polarized light and the p-polarized light in reflected light reflected from a surface of the top anti-reflection coating, wherein
incident angle of the exposure light incident on the top anti-reflection coating is calculated according to the equation:
θᵢ=arc sin(NA)
where θᵢ is the incident angle of the exposure light incident on the top anti-reflection coating, and NA is the numerical aperture of an aligner, and
the thickness of the top anti-reflection coating is calculated according to the equation:
d=λ/(4n cos θₜ)
where d is the thickness of the top anti-reflection coating, λ is a wavelength of the exposure light, n is the refractive index of the top anti-reflection coating, and θₜ is the incident angle of the exposure light within the top anti-reflection coating;
determining, based on the relationships calculated, a refractive index of the top anti-reflection coating reducing the ratio of the energy of the s-polarized light to the energy of the p-polarized light in the reflected light; and
determining, based on the refractive index determined, a thickness for the top anti-reflection coating according to the equation: d=λ/(4n cos θₜ), wherein forming the top anti-reflection coating includes forming the top anti-reflection coating to have the refractive index determined and the thickness determined.

7. The exposure method as claimed in claim 6, further comprising:
calculating, based on the refractive index determined and the thickness determined for the top anti-reflection coating, a proportion of the energy of the s-polarized light in the energy of the exposure light absorbed into the resist film for each incident angle of the exposure light incident on the top anti-reflection coating, with the thickness of the resist film used as a parameter; and
determining, based on the proportion calculated, a thickness for the resist film with respect to the numerical aperture of the aligner to increase the proportion of the energy of the s-polarized light, wherein forming the resist film includes forming the resist film to have the thickness determined for the resist film.

8. The exposure method as claimed in claim 1, further comprising forming an antireflective film between the substrate to be processed and the resist film.

9. The exposure method as claimed in claim 1, wherein the exposure light has a wavelength of no more than 193 nm.

10. The exposure method as claimed in claim 1, including irradiating the resist film with the exposure light through an aligner having a numerical aperture of at least 0.68.
